(19) United States
(12) Patent Application Publication
(10) Pub. No.: US 2025/0385662 A1
(43) Pub. Date: Dec. 18, 2025

(54) OSCILLATOR THAT PERFORMS LINEAR FREQUENCY MODULATION UPON OSCILLATION SIGNAL OUTPUT TO DC-TO-DC CONVERTER UNDER VOLTAGE MODE

(71) Applicant: Elite Semiconductor Microelectronics Technology Inc., Hsinchu (TW)

(72) Inventor: Yao-Wei Yang, Hsinchu (TW)

(73) Assignee: Elite Semiconductor Microelectronics Technology Inc., Hsinchu (TW)

(21) Appl. No.: 18/743,077

(22) Filed: Jun. 13, 2024

(51) Int. Cl. H03K 5/01

(52) U.S. Cl. CPC H03K 5/01; H03B 5/1228

(57) ABSTRACT

The oscillator includes a reference current generating circuit, a voltage modulator circuit, and an oscillating circuit. The reference current generating circuit is arranged to generate a reference current. The voltage modulator circuit is arranged to receive a feedback voltage, and perform a voltage modulation operation according to a first reference voltage and the feedback voltage, to generate a modulated voltage. The oscillating circuit is coupled to the reference current generating circuit and the voltage modulator circuit, and arranged to generate an oscillation signal with an oscillation frequency according to the reference current and the modulated voltage.

### BACKGROUND OF THE INVENTION

### 1. Field of the Invention

The present invention is related to frequency modulation, and more particularly, to an oscillator that can perform a linear frequency modulation upon an oscillation signal output to a direct current (DC)-to-DC converter under a voltage mode.

### 2. Description of the Prior Art

For a DC-to-DC converter, during an initial starting up phase, an output voltage of the DC-to-DC converter may suffer from drastic ringing problems. At this moment, the output voltage may be relatively low, which may cause an inductor current of the DC-to-DC converter to have a larger slope, and therefore make it difficult to control the inductor current at a high frequency. In addition, when an output terminal of the DC-to-DC converter is short-circuited to ground, a voltage difference between an input voltage and the output voltage may be quite large, which may also cause the inductor current to have a larger slope, and therefore cause damage to the DC-to-DC converter.

In order to address the above-mentioned issues, a frequency modulation operation may be performed upon an oscillation signal generated by an oscillator of the DC-to-DC converter, so that a current sensing operation performed upon the inductor current can effectively reflect changes of the inductor current. For a conventional method, a frequency hopping modulation operation may be performed, however, the disadvantage is that it may cause drastic changes in the output voltage and the inductor current.

### SUMMARY OF THE INVENTION

It is therefore one of the objectives of the present invention to provide an oscillator that can perform a linear frequency modulation upon an oscillation signal output to a DC-to-DC converter under a voltage mode, to address the above-mentioned issues.

According to an embodiment of the present invention, an oscillator is provided. The oscillator comprises a reference current generating circuit, a voltage modulator circuit, and an oscillating circuit. The reference current generating circuit is arranged to generate a reference current. The voltage modulator circuit is arranged to receive a feedback voltage, and perform a voltage modulation operation according to a first reference voltage and the feedback voltage, to generate a modulated voltage. The oscillating circuit is coupled to the reference current generating circuit and the voltage modulator circuit, and arranged to generate an oscillation signal with an oscillation frequency according to the reference current and the modulated voltage.

One of the benefits of the present invention is that, by the oscillator of the present invention applied to a DC-to-DC converter, the overshoot/undershoot of the induction current of the DC-to-DC converter can be effectively suppressed by performing a linear frequency modulation operation. In addition, during a start-up period of a pre-biased output of the DC-to-DC converter, the changes in the output voltage of the DC-to-DC converter for the linear frequency modulation operation can be smoother than that for a frequency hopping modulation operation.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram illustrating a relationship between a DC-to-DC converter and an oscillator according to an embodiment of the present invention.

FIG. 2 is a diagram illustrating an oscillator according to an embodiment of the present invention.

FIG. 3 is a diagram illustrating a voltage modulator circuit according to an embodiment of the present invention.

### DETAILED DESCRIPTION

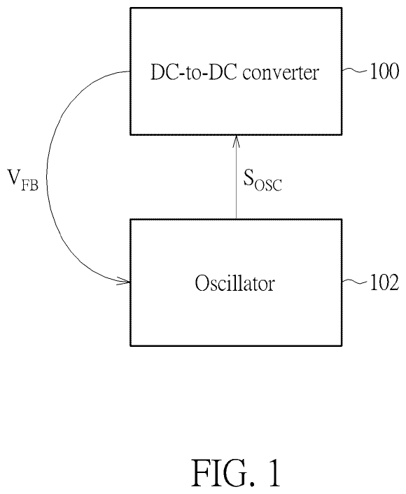

FIG. 1 is a block diagram illustrating a relationship between a DC-to-DC converter 100 and an oscillator 102 according to an embodiment of the present invention. Examples of the DC-to-DC converter 100 may include, but are not limited to: a buck converter or a boost converter. The DC-to-DC converter 100 may convert an input DC voltage into a stable output DC voltage, and provide the output voltage to a connected load (not shown in FIG. 1). The oscillator 102 may output an oscillation signal S_{OSC} with an oscillation frequency F_{OSC} to the DC-to-DC converter 100. In this embodiment, a feedback voltage V_{FB} may be derived from the output voltage of the DC-to-DC converter 100 (e.g., may be obtained by performing a voltage division operation upon the output voltage), and the feedback voltage V_{FB} may be provided to the oscillator 102 for performing a linear frequency modulation upon the oscillation frequency F_{OSC} under a voltage mode.

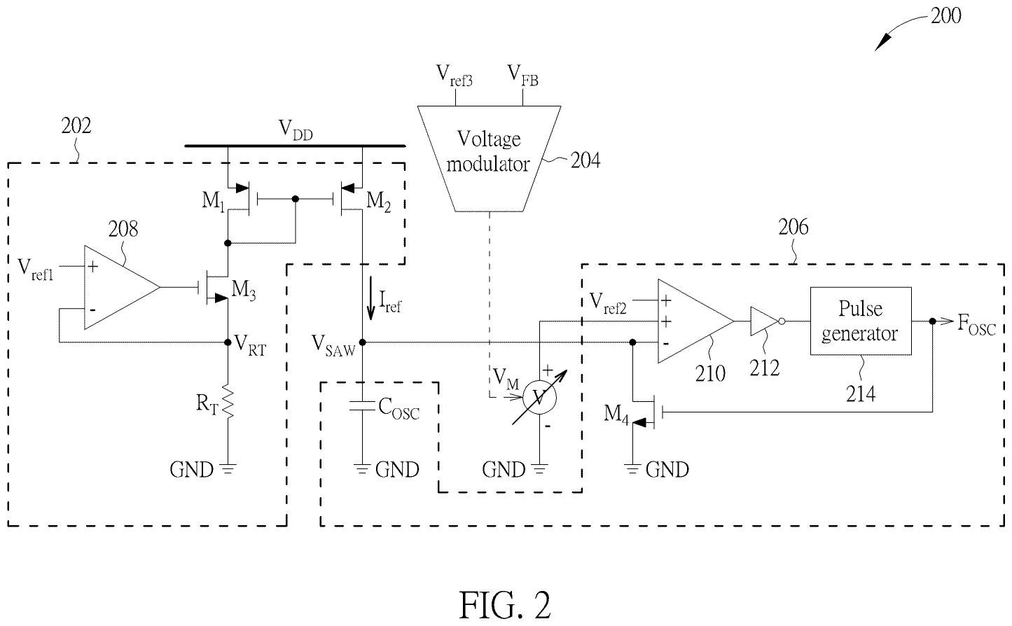

In detail, refer to FIG. 2. FIG. 2 is a diagram illustrating an oscillator 200 according to an embodiment of the present invention, wherein the oscillator 102 shown in FIG. 1 may be implemented by the oscillator 200. As shown in FIG. 2, the oscillator 200 may include a reference current generating circuit 202, a voltage modulator circuit 204, and an oscillating circuit 206. The reference current generating circuit 202 may include an amplifier 208, multiple p-type transistors M₁ and M₂, an n-type transistor M₃, and a resistor R_{T}, wherein the p-type transistors M₁ and M₂ form a current mirror. The amplifier 208 has a non-inverting input terminal coupled to a reference voltage V_{ref1} (labeled as “+” in FIG. 2), an inverting input terminal coupled to a source terminal of the n-type transistor M₃ (labeled as “−” in FIG. 2), and an output terminal coupled to a gate terminal of the n-type transistor M₃. The resistor R_{T} has a first terminal coupled to the source terminal of the n-type transistor M₃ and a second terminal coupled to a grounding voltage GND. The p-type transistor M₁ has a source terminal coupled to a supply voltage V_{DD}, a drain terminal coupled to a drain terminal of the n-type transistor M₃, and a gate terminal coupled to the drain terminal of the p-type transistor M₁. The p-type transistor M₂ has a source terminal coupled to the supply voltage V_{DD} and a gate terminal coupled to the gate terminal of the p-type transistor M₁. The current mirror composed of the p-type transistors M₁ and M₂ may generate a mirror current I_{ref} according to a current flowing through the resistor R_{T}.

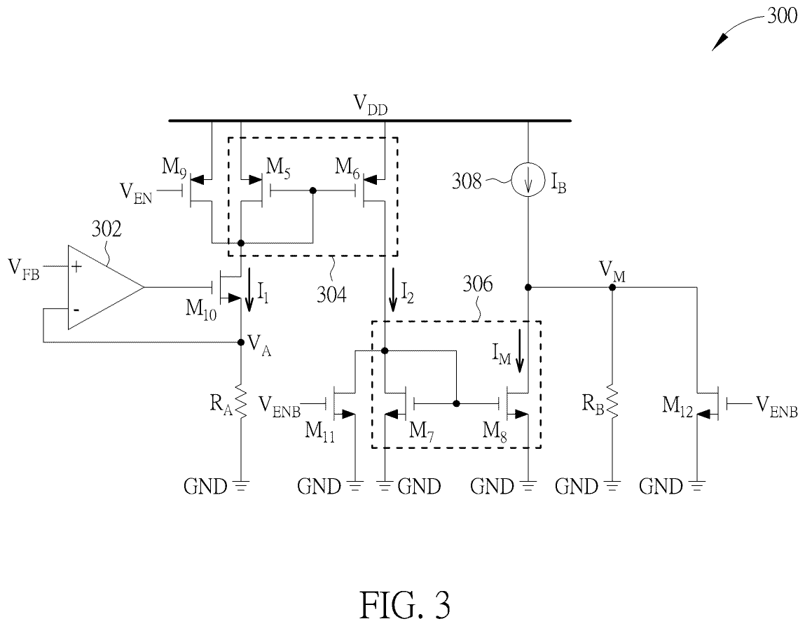

The voltage modulator circuit 204 may be arranged to receive the feedback voltage V_{FB} from the DC-to-DC converter 100, and perform a voltage modulation operation according to a reference voltage V_{ref3} and the feedback voltage V_{FB}, to generate a modulated voltage V_{M}. Specifically, refer to FIG. 3. FIG. 3 is a diagram illustrating a voltage modulator circuit 300 according to an embodiment of the present invention, wherein the voltage modulator circuit 204 shown in FIG. 2 may be implemented by the voltage modulator circuit 300. As shown in FIG. 3, the voltage modulator circuit 300 may include an amplifier 302, multiple current mirrors 304 and 306, a current source 308, multiple resistors R_{A} and R_{B}, multiple n-type transistors M₇, M₈, M₁₀, M₁₁, and M₁₂, and multiple p-type transistors M₅, M₆, and M₉. The amplifier 302 has a non-inverting input terminal arranged to receive the feedback voltage V_{FB} from the DC-to-DC converter 100 (labeled as “+” in FIG. 3), an inverting input terminal coupled to a source terminal of the n-type transistor M₁₀ (labeled as “−” in FIG. 3), and an output terminal coupled to a gate terminal of the n-type transistor M₁₀. The resistor R_{A} has a first terminal coupled to the source terminal of the n-type transistor M₁₀ and a second terminal coupled to the grounding voltage GND.

The current mirror 304 may be coupled between a drain terminal of the n-type transistor M₁₀ and the supply voltage V_{DD}, and may be arranged to generate a mirror current I₂ according to a current I₁ flowing through the resistor R_{A}, wherein under a condition that a voltage value of the feedback voltage V_{FB} at the non-inverting input terminal of the amplifier 302 is approximately equal to that of a voltage V_{A} at the first terminal of the resistor R_{A}, a current value of the current I₁ may be derived from the equation:

$${I}_{1} = \frac{{V}_{F B}}{{R}_{A}} .$$

Specifically, the current mirror 304 may be composed of the p-type transistors M₅ and M₆. The p-type transistor M₅ has a source terminal coupled to the supply voltage V_{DD}, a drain terminal coupled to the drain terminal of the n-type transistor M₁₀, and a gate terminal coupled to the drain terminal of the p-type transistor M₅. The p-type transistor M₆ has a source terminal coupled to the supply voltage V_{DD} and a gate terminal coupled to the gate terminal of the p-type transistor M₅. Assume that a ratio of a width of the p-type transistor M₅ over a length of the p-type transistor M₅ to a width of the p-type transistor M₆ over a length of the p-type transistor M₆ is 1 to k. Under this situation, a current value of the mirror current I₂ may be k times that of the current I₁ (i.e., I₂=k*I₁).

The current mirror 306 may be coupled between a drain terminal of the p-type transistor M₆ and the grounding voltage GND, and may be arranged to generate a mirror current I_{M} according to the mirror current I₂. Specifically, the current mirror 306 may be composed of the n-type transistors M₇ and M₈. The n-type transistor M₇ has a drain terminal coupled to a drain terminal of the p-type transistor M₆, a source terminal coupled to the grounding voltage GND, and a gate terminal coupled to the drain terminal of the n-type transistor M₇. The n-type transistor M₈ has a drain terminal coupled to the current source 308, a source terminal coupled to the grounding voltage GND, and a gate terminal coupled to the gate terminal of the n-type transistor M₇, wherein the modulated voltage V_{M} is generated at the drain terminal of the n-type transistor M₈. Assume that a ratio of a width of the n-type transistor M₇ over a length of the n-type transistor M₇ to a width of the n-type transistor M₈ over a length of the n-type transistor M₈ is 1 to n. Under this situation, a current value of the mirror current I_{M} may be n times that of the current I₂

$$( i . e . , {I}_{m} = n ⋆ {I}_{2} = k ⋆ n ⋆ {I}_{1} = k ⋆ n ⋆ \frac{{V}_{F B}}{{R}_{A}} ) .$$

The current source 308 may be arranged to provide a supply current I_{B}. The resistor Re has a first terminal coupled between the current source 308 and the current mirror 306, and a second terminal coupled to the grounding voltage GND, wherein the modulated voltage V_{M} is generated at the first terminal of the resistor R_{B}. In this embodiment, a voltage value of the reference voltage V_{ref3} may be preset to be equal to a product of a current value of the supply current I_{B} and a resistance value of the resistor R_{B} (i.e., V_{ref3}=I_{B}*R_{B}), wherein a voltage value of the reference voltage V_{ref3} is greater than or equal to that of the modulated voltage V_{M} (i.e., V_{ref3}≥V_{M}), and a voltage value of the supply voltage V_{DD} is greater than or equal to that of the reference voltage V_{ref3} (i. e., V_{DD}≥V_{ref3}). The voltage value of the modulated voltage V_{M} may be equal to a product of a current value difference between the supply current I_{B} and the mirror current I_{M} and a resistance value of the resistor R_{B} (i.e., V_{M}=(I_{B}−I_{M})*R_{B}). Since V_{ref3}=I_{B}*R_{B} and

$${I}_{M} = k * n * \frac{{V}_{F B}}{{R}_{A}} ,$$

the voltage value of the modulated voltage V_{M} can be derived from the equation:

$${V}_{M} = {V}_{ref 3} - k * n * {V}_{F B} * \frac{{R}_{B}}{{R}_{A}} .$$

In addition, each of the p-type transistor M₉, the n-type transistor M₁₁, and the n-type transistor M₁₂ may be regarded as a switching circuit. The p-type transistor M₉ has a source terminal coupled to the supply voltage V_{DD}, a drain terminal coupled to the drain terminal of the p-type transistor M₅, and a gate terminal arranged to receive a first switching voltage V_{EN}. The n-type transistor M₁₁ has a source terminal coupled to the grounding voltage GND, a drain terminal coupled to the drain terminal of the p-type transistor M₆, and a gate terminal arranged to receive a second switching voltage V_{ENB}, wherein the second switching voltage V_{ENB} is an inverse of the first switching voltage V_{EN}. The n-type transistor M₁₂ has a source terminal coupled to the grounding voltage GND, a drain terminal coupled to the first terminal of the resistor R_{B}, and a gate terminal arranged to receive the second switching voltage V_{ENB}. In response to the first switching voltage V_{EN} being at a high level (i.e., the second switching voltage V_{ENB} is at a low level), all of the p-type transistor M₉, the n-type transistor M₁₁, and the n-type transistor M₁₂ are turned off, and the voltage value of the modulated voltage V_{M} may be derived by the above-mentioned equation

$$( i . e . , {V}_{m} = {V}_{ref 3} - k * n * {V}_{FB} * \frac{{R}_{B}}{{R}_{A}} ) .$$

In response to the first switching voltage V_{EN} being at a low level (i.e., the second switching voltage V_{ENB} is at a high level), all of the p-type transistor M₉, the n-type transistor M₁₁, and the n-type transistor M₁₂ are turned on, and the voltage value of the modulated voltage V_{M} may be 0.

Refer back to FIG. 2. The oscillating circuit 206 may be coupled to the reference current generating circuit 202 and the voltage modulator circuit 204, and may be arranged to generate the oscillation signal S_{OSC} with the oscillation frequency F_{OSC} according to the reference current I_{ref} and the modulated voltage V_{M}. In detail, the oscillating circuit 206 may include a comparator 210, an inverter 212, a pulse generator 214, an n-type transistor M₄, and a capacitor C_{OSC}. The capacitor C_{OSC} has a first terminal and a second terminal, wherein the first terminal is coupled to the reference current generating circuit 202 for receiving the reference current I_{ref}, the second terminal is coupled to the grounding voltage GND, and a voltage V_{SAW} is generated according to the reference current I_{ref} and the capacitor C_{OSC} at the first terminal. The comparator 210 has a first non-inverting input terminal coupled to a reference voltage V_{ref2}(labeled as “+” in FIG. 2), a second non-inverting input terminal coupled to the modulated voltage V_{M} (labeled as “+” in FIG. 2), and an inverting input terminal coupled to the first terminal of the capacitor C_{OSC} for receiving the voltage V_{SAW} (labeled as “−” in FIG. 2), wherein a voltage value of the modulated voltage V_{M} is greater than or equal to that of reference voltage V_{ref2} (i.e., V_{M}≥V_{ref2}). The n-type transistor M₄ has a source terminal coupled to the grounding voltage GND, a drain terminal coupled to the inverting input terminal of the comparator 210, and a gate terminal coupled to an output terminal of the pulse generator 214.

The comparator 210 may be arranged to perform a comparison operation according to the reference voltage V_{ref}, the modulated voltage V_{M}, and the voltage V_{SAW}, to generate a comparison result. The inverter 212 may be coupled to an output terminal of the comparator 210, and may be arranged to perform an inversion operation upon an output of the comparator 210 (i.e., the comparison result) to generate an inverted result. The pulse generator 214 may be arranged to generate the oscillation signal S_{OSC} with the oscillation frequency F_{OSC} according to the inverted result. The oscillation frequency F_{OSC} may be linearly modulated through the following equation:

$${F}_{OSC \_ ORI} = D * {F}_{OSC \_ MOD}$$

wherein F_{OSC_ORI} is an original oscillation frequency, F_{OSC_MOD} is a modulated oscillation frequency, D is a ratio of the modulated voltage V_{M} to the reference voltage V_{ref2}

$$( i . e . , D = \frac{{V}_{M}}{{V}_{ref 2}} ) ,$$

and D is greater than or equal to 1 (i.e., D≥1). Since the architecture of the oscillating circuit 206 is well known to those skilled in the art, and the focus of the present invention is on the linear frequency modulation, the detailed operations of the oscillating circuit 206 are omitted here for brevity.

In summary, by the oscillator of the present invention applied to a DC-to-DC converter, the overshoot/undershoot of the induction current of the DC-to-DC converter can be effectively suppressed by performing a linear frequency modulation operation. In addition, during a start-up period of a pre-biased output of the DC-to-DC converter, the changes in the output voltage of the DC-to-DC converter for the linear frequency modulation operation can be smoother than that for a frequency hopping modulation operation.

Those skilled in the art will readily observe that numerous modifications and alterations of the device and method may be made while retaining the teachings of the invention. Accordingly, the above disclosure should be construed as limited only by the metes and bounds of the appended claims.

1. An oscillator, comprising:
a reference current generating circuit, arranged to generate a reference current;
a voltage modulator circuit, arranged to receive a feedback voltage, and perform a voltage modulation operation according to a first reference voltage and the feedback voltage, to generate a modulated voltage; and
an oscillating circuit, coupled to the reference current generating circuit and the voltage modulator circuit, and arranged to generate an oscillation signal with an oscillation frequency according to the reference current and the modulated voltage;
wherein the voltage modulator circuit comprises:
an n-type transistor;
an amplifier, having a non-inverting input terminal arranged to receive the feedback voltage, an inverting input terminal coupled to a source terminal of the n-type transistor, and an output terminal coupled to a gate terminal of the n-type transistor;
a first resistor, having a first terminal coupled to the source terminal of the n-type transistor and a second terminal coupled to a second reference voltage;
a first current mirror, coupled between a drain terminal of the n-type transistor and a third reference voltage, and arranged to generate a first mirror current according to a current flowing through the first resistor, wherein a voltage value of the second reference voltage is less than a voltage value of the third reference voltage;
a second current mirror, coupled between the first current mirror and the second reference voltage, and arranged to generate a second mirror current according to the first mirror current;
a current source, arranged to provide a supply current; and
a second resistor, having a first terminal coupled between the current source and the second current mirror and a second terminal coupled to the second reference voltage.

2. The oscillator of claim 1, wherein the oscillator is applied to a direct current (DC)-to-DC converter, the oscillation signal is output to the DC-to-DC converter, and the feedback voltage is from the DC-to-DC converter.

3. (canceled)

4. The oscillator of claim 1, wherein the modulated voltage is generated at the first terminal of the second resistor.

5. The oscillator of claim 1, wherein a voltage value of the first reference voltage is equal to a product of a current value of the supply current and a resistance value of the second resistor.

6. The oscillator of claim 1, wherein the first current mirror comprises:
a first p-type transistor, having a source terminal coupled to the third reference voltage, a drain terminal coupled to the drain terminal of the n-type transistor, and a gate terminal coupled to the drain terminal of the first p-type transistor; and
a second p-type transistor, having a source terminal coupled to the third reference voltage and a gate terminal coupled to the gate terminal of the first p-type transistor.

7. The oscillator of claim 6, wherein the second current mirror comprises:
a first n-type transistor, having a drain terminal coupled to a drain terminal of the second p-type transistor, a source terminal coupled to the second reference voltage, and a gate terminal coupled to the drain terminal of the first n-type transistor; and
a second n-type transistor, having a drain terminal coupled to the current source, a source terminal coupled to the second reference voltage, and a gate terminal coupled to the gate terminal of the first n-type transistor, wherein the modulated voltage is generated at the drain terminal of the second n-type transistor.

8. The oscillator of claim 1, wherein a voltage value of the first reference voltage is greater than or equal to a voltage value of the modulated voltage.

9. The oscillator of claim 1, wherein the oscillating circuit comprises:
a capacitor, having a first terminal coupled to the reference current generating circuit and a second terminal coupled to the second reference voltage;
a comparator, having a first non-inverting input terminal coupled to a fourth reference voltage, a second non-inverting input terminal coupled to the modulated voltage, and an inverting input terminal coupled to the first terminal of the capacitor;
an inverter, coupled to an output terminal of the comparator, and arranged to perform an inversion operation upon an output of the comparator to generate an inverted result;
a pulse generator, arranged to generate the oscillation signal according to the inverted result; and
an n-type transistor, having a drain terminal coupled to the inverting input terminal of the comparator, a source terminal coupled to the second reference voltage, and a gate terminal coupled to an output terminal of the pulse generator.

10. The oscillator of claim 9, wherein a voltage value of the modulated voltage is greater than or equal to a voltage value of the fourth reference voltage.
